(19) United States
(12) Patent Application Publication
(10) Pub. No.: US 2005/0118735 A1
(43) Pub. Date: Jun. 2, 2005

(54) Method for determining or inspecting a property of a patterned layer

(76) Inventors: Ulrich Mantz, Dresden (DE); Peter Weidner, Roetz (DE); Ralph Wienhold, Dresden (DE); Pierre-Yves Guittet, Dresden (DE)

Correspondence Address: GERO G. McCLELLAN;MOSER, PATTERSON & SHERIDAN, L.L.P., Suite 1500, 3040 Post Oak Blvd., Houston, TX, 77056, US

(21) Appl. No.: 10/960,327

(22) Filed: Oct. 7, 2004

(30) Foreign Application Priority Data
Oct. 9, 2003 (DE) DE 103 46 850.1

(51) Int. Cl. H01L 21/00; H01L 21/76

(52) U.S. Cl. 438/5

(57) ABSTRACT

One embodiment of the invention provides a method for determining or inspecting a lateral dimension or a volume of a recess in a layer at a surface of a substrate or a property of a material arranged in the recess. The layer having the recess is irradiated with an electromagnetic scanning radiation having a wavelength that is greater than a lateral dimension of the recess, and an electromagnetic response radiation that emerges from an interaction of the scanning radiation with the layer having the recess is received. Characterization data, which characterize the interaction between the layer having the recess and the scanning radiation, are ascertained from the received electromagnetic response radiation, the characterization data mapping the lateral dimension or the volume of the recess or the property of the material arranged in the recess. The lateral dimension or the volume of the recess or the property of the material arranged in the recess is determined or inspected on the basis of the characterization data.

### CROSS-REFERENCE TO RELATED APPLICATIONS

This application claims foreign priority benefits under 35 U.S.C. §119 to co-pending German patent application number DE 103 46 850.1, filed 9 Oct. 2003. This related patent application is herein incorporated by reference in its entirety.

### BACKGROUND OF THE INVENTION

1. Field of the Invention

The present invention relates to a method for determining or inspecting a property of a patterned layer at a surface of a substrate, in particular, a lateral dimension or a volume of a recess in the layer or a property of a material arranged in the recess.

2. Description of the Related Art

In integrated circuits, individual components are arranged at an ever smaller mutual distance on a chip. The standard in the case of DRAM technology is currently a few tens of nm. Therefore, electrical interactions, crosstalk and leakages of critical currents increasingly occur. In order to prevent such electrical interactions between the individual components, isolation trenches are used between the individual components. Shallow isolation trenches, in particular, are in widespread use in this case. Shallow trench isolation (STI) is a widespread technology. It has gained in complexity in past years and today meets both the requirements imposed in connection with logic products and the requirements imposed in connection with memory products or memory-embedded products. The monitoring and measurement of isolation trenches is a critical process step in this case. Particularly in logic products, isolation trenches are generally not arranged regularly or symmetrically, but rather are distributed quasi-randomly over the wafer.

The STI method for producing an electrical isolation between individual components of an integrated circuit fundamentally consists of forming a trench between the components, depositing an oxide or else a different insulator with a layer thickness that is greater than the depth of the trench, and removing the projection by means of chemical mechanical polishing (CMP). By means of the CMP step, the surface becomes approximately planar, and any oxide projecting beyond the surface is removed. In this case, the isolation trench may essentially completely surround the electrical component in order to isolate it from other active electrical regions, in particular other electronic components.

In order to be able to efficiently control and carry out the filling of the isolation trench and the CMP step, it is necessary to monitor the etching depth and the trench profile as first-order parameters which are critical for the STI process. In order to model or predict the electrical behavior of a component which is essentially or completely enclosed by an isolation trench, in particular a shallow isolation trench or an STI, a more precise analysis over and above that of the etch depth and trench profile is necessary, however. The parameters that are relevant for this purpose include the thicknesses and the physical properties (for example conductivity, dopant concentration and resistance) of individual layers. These parameters have to be monitored and tracked in order to predict the electrical behavior in the vicinity of STIs.

Many conventional methods exist for the occasional, periodic or quasi-continuous monitoring of the parameters mentioned along a production line. One important method is atomic force microscopy (AFM), which represents the preferred industrial solution. Atomic force microscopy is a mature monitoring tool for the production of feature sizes down to approximately 70 nm. However, it yields only incomplete information about patterned regions such as holes, trenches, isolation trenches and, in particular, shallow isolation trenches. Atomic force microscopy yields only a total etching depth and an etching depth profile. Complementary destructive methods are required for a complete characterization of the structure examined. The disadvantages and limitations of atomic force microscopy include, in particular, the following points:
The throughput of an atomic force microscope is low, with at present a maximum of approximately 7 wafers per hour.
Deep structures can be detected only to a limited extent by atomic force microscopy. The form of the AFM tip in particular represents a limiting factor for the detection of deep trenches.
Atomic force microscopy yields only global geometric information (for example, a surface profile and a total depth). Detailed information with regard to individual layers (thickness, material properties, etc.) is not afforded.
Atomic force microscopy depends on the randomly spread quality of the specially manufactured AFM tips, which furthermore constitute expensive consumerable and spare parts.
The use of atomic force microscopy is currently limited by the feature sizes of the technology. If the structures examined are holes having a small diameter (for example, <70 nm), atomic force microscopy cannot yield precise measurements since the AFM tips cannot penetrate, or cannot penetrate completely, into these holes. This represents a limiting factor for use in future technology steps.
Atomic force microscopy is a discrete measurement method since, in one pass, it only scans a very limited region in each case. A very large number of measurements have to be carried out in order to acquire statistical data.
In the case of extended patterned regions, for example in the case of STI regions, atomic force microscopy is limited by its maximum scanning length and complicated geometries. In particular, atomic force microscopy cannot characterize extended regions with a random or quasi-random structure.
Atomic force microscopy does not yield information about filling factors and is not suitable for a chemical characterization.

Methods and apparatuses for detecting surface profiles, in particular so-called surface profilers, essentially have the same limitations as atomic force microscopy, but the scanning length is greater and the sensitivity is lower than in atomic force microscopy.

In this connection, scanning electron microscopy represents a destructive method since a wafer first has to be broken in order, at the break, to be able to detect a vertical structure by means of scanning electron microscopy. Furthermore, scanning electron microscopy suffers from a highly restricted throughput and does not afford a solution for a high scanning rate on a production line.

Measurement by detecting scattered light, which is also known as scatterometry, is competing with scanning electron microscopy and atomic force microscopy with regard to the detection of patterned regions (STI, recesses, etc.). It can also be used with feature sizes of 90 nm and 70 nm, but likewise has a series of disadvantages, including:
Scatterometry can at present only be applied to periodic one-dimensional test structures (for example gratings made from spaced-apart lines) besides the actual array to be produced. Periodic or random or quasi-random two- or three-dimensional features in an array cannot be detected. For an application in connection with STI, a correlation between a periodic test structure and the quasi-random structures in the actual array has to be found for each new layout of the integrated circuit or else only of the isolation trenches.
Statistical data on real integrated circuits or components are not afforded.
The trench depth is restricted to approximately 1 μm. Deep trenches, for example, having a depth of 6 μm to 8 μm, as are currently used in numerous applications, cannot be measured.

A problem or an objective for which there is no satisfactory solution whatsoever at the present time is the detection of sidewall layers or sidewall coatings in recesses and the layer thicknesses thereof. By way of example, recesses are lined with tetraethyl orthosilicate (TEOS) silicon oxide layers produced from tetraethyl orthosilicate by chemical vapor deposition. Currently, no satisfactory method has been developed for detecting the thickness of such a TEOS collar or edge. For advanced process control or method monitoring, however, it is necessary to know the thickness of such a TEOS layer.

In particular, atomic force microscopy of critical dimensions, which could be suitable for this application, in principle, cannot be applied to the feature sizes of 90 nm and 70 nm that are currently being developed. Exactly ascertaining the form or shape of the AFM tip also poses problems which reduce the accuracy of the measurement of relatively large ground conductors. A further problem is the limited depth that can be scanned.

Scatterometry is also not yet suitable at the present time for detecting the TEOS layer thicknesses described since scatterometry has not yet been developed far enough. Scatterometry is driving forward development in the direction of small ground conductors; large ground conductors (approximately 0.5 μm) are not at the center of interest. Furthermore, scatterometry has limitations with regard to deep structures (for example, 8 μm).

Therefore, a need exists for a method for determining or inspecting a lateral dimension or a volume of a recess in a layer at a surface of a substrate or a property of a material arranged in the recess and an associated method for fabricating a component with a recess in a layer.

### SUMMARY OF THE INVENTION

One aspect of the present invention is to provide a method for determining or inspecting a lateral dimension or a volume of a recess in a layer at a surface of a substrate or a property of a material arranged in the recess and an associated method for fabricating a component with a recess in a layer.

One embodiment of the present invention provides a method for determining or inspecting a lateral dimension or a volume of a recess in a layer at a surface of a substrate or a property of a material arranged in the recess, in which the layer having the recess is irradiated with an electromagnetic scanning radiation having a wavelength that is greater than a lateral dimension of the recess. An electromagnetic response radiation emerges from an interaction between the scanning radiation and the layer having the recess, the response radiation being received. Characterization data that characterize the interaction between the layer having the recess and the scanning radiation are ascertained from the received electromagnetic response radiation. The characterization data maps the lateral dimension or the volume of the recess or the property of the material arranged in the recess. The lateral dimension or the volume of the recess or the property of the material arranged in the recess is determined or inspected on the basis of the characterization data.

The method according to one embodiment of the invention enables a lateral dimension or a volume of a recess in a layer or a property of a material arranged in the recess to be ascertained nondestructively. The method can thus be used for process control within the production line. A wafer or some other substrate to which the method according to one embodiment of the invention is applied can subsequently be processed further since the wafer or the substrate is neither destroyed nor damaged during the method according to one embodiment of the invention. According to one embodiment of the invention, the method lowers the costs to a considerable extent and also makes it possible, if necessary, to detect or inspect each individual wafer prior to further processing. The method thus serves for optimizing the method for fabricating components with recesses in layers and, in particular, integrated semiconductor circuits. Thus, the yield of the fabrication methods may be significantly improved, which enables the fabrication costs to be lowered.

A further advantage of the method according to one embodiment of the invention is that it does not require any sample preparation and can be carried out within a very short time. Therefore, it enables a high throughput of up to 15 wafers per hour or more in comparison with the conventional methods described above.

Furthermore, the method according to one embodiment of the invention yields both global and detailed geometric information or dimensions such as, for example, the total etching depth and the thickness of an individual layer. Moreover, the method according to one embodiment of the invention enables access to physical properties of layers, for example electrical properties, dopant levels and concentrations.

The abovementioned advantages lead to a reduction of the physical failure analysis (PFA). In particular, embodiments of the present invention enable a better understanding of the electrical behavior for modeling purposes, and more parameters are detected at the same time.

A further advantage is that no scattering effects occur at a wavelength that is greater than the typical feature size and thus, in particular, greater than a lateral dimension of a recess. This advantage is manifested particularly distinctly in the case of the use of infrared light, since the wavelength thereof is typically ten to hundred times as long as the critical dimension in modern semiconductor structures. Therefore, embodiments of the present invention are not restricted to a specific technology step. Moreover, embodiments of the present invention are not restricted with regard to the structure depth. Information can actually be obtained from the top side to as far as the underside of a component.

In the course of an individual measurement, a large number of structures, in particular trenches and other recesses, may be measured. The measurement result is an average value over a large number (up to a few thousand or more) of structures.

A further important advantage provided by embodiments of the present invention is that the measurements are performed on real components or substrates/wafers, instead of test structures. The critical equivalence (during measurements on test structures) of the test structures with the real structures or structures that are actually of interest and, consequently, the transferability of the measurement results from the test structures to the real structures are consequently insignificant.

In the case of the method according to one embodiment of the invention, the electromagnetic scanning radiation simultaneously or successively comprises a plurality of discrete wavelengths or a continuous spectrum of wavelengths. In this case, the characterization data may comprise, in particular, a reflectivity spectrum.

Furthermore, linearly polarized scanning radiation may be used, and the step of receiving the electromagnetic response radiation may comprise ascertaining the polarization of the response radiation. One embodiment of the present invention thus uses the method of infrared spectroscopic ellipsometry (IRSE). As an alternative, the method according to one embodiment of the invention is performed by infrared spectroscopy without detection of the polarization (IRS).

Both infrared spectroscopy (IRS) and infrared spectroscopic ellipsometry (IRSE) enable simple process control by comparing the spectrum respectively obtained with a reference spectrum. As long as differences between the detected spectrum and the reference spectrum do not exceed a predetermined threshold, the structures of the layer examined also do not deviate significantly from those of a reference layer at which the reference spectrum was obtained.

To obtain more precise and potentially very detailed information about structures in the layer, in particular about lateral dimensions or volumes of recesses or properties of materials arranged in the recesses, the IRS or the IRSE is combined with modeling. For this purpose, a model layer is postulated, for which model characterization data that characterize the interaction of the model layer with the scanning radiation are simulated or calculated. The model layer or its mathematical description has at least one free parameter on which the model characterization data depend. A value for which the model characterization data and the characterization data are identical or have a maximum similarity is ascertained for the free parameter, i.e., the model characterization data are fitted to the characterization data detected empirically for the layer examined.

The lateral dimension or the volume of the recess or the property of the material arranged in the recess is ascertained from the ascertained value of the free parameter. The model layer may be laterally homogeneous, and the free parameter may describe a material composition or a thickness of the model layer. The lateral dimension or the volume of the recess or the property of the material arranged in the recess is then determined from the material composition or the thickness of the laterally homogeneous model layer.

Particularly for a model whose model characterization data are fitted to the characterization data obtained empirically, a plurality of process parameters may be monitored simultaneously. Embodiments of the present invention thus go far beyond the prior art, in which, by way of example, an AFM tip detects a surface profile but yields no information whatsoever about the material directly below the surface. By contrast, one embodiment of the present invention yields the total etching depth, individual layer thicknesses (nitride areas, depths below the silicon), physical properties of individual layers, chemical characteristics, trench profiles, material concentrations, material properties, filling factors, chemical characteristics, etc.

In the transition to a future technology step (e.g., 90 nm, 70 nm, 55 nm, etc.), only a few well-defined parameters have to be altered in the model or in the model layer. Embodiments of the present invention require neither a development of new hardware nor an alteration of existing hardware, but rather, the mature hardware that is already present for IRSE can be used. Embodiments of the present invention, which combine IRSE with powerful modeling, constitute highly flexible solutions, with the following advantages or features.

As an optical method, the method according to one embodiment of the invention, in particular also in the variant with IRS or IRSE, constitutes a contactless measurement. The method therefore does not result in destruction of or damages to the sample and does not rely on expensive wearing parts such as the AFM tips. In contrast, for example, to the abovementioned atomic force microscopy, the method according to one embodiment of the invention is also not randomly dependent on the quality of expensive spare or wearing parts.

The method according to one embodiment of the invention is suitable both for the ex-situ analysis of components and for the in-situ monitoring of STI and other processes. It enables an in-situ monitoring of STI etching depths and etching profiles in real time, and thus also enables a faster parameter feedback to plasma etching tools and a faster parameter feedforward for the control of CMP tools. Embodiments of the present invention may be developed into an integrated metrology tool.

The apparatus costs or procurement costs of an infrared spectroscopic ellipsometer are similar to those of an atomic force microscope, but the ellipsometer has a higher number of applications in the field of metrology in contrast to the microscope. The operating costs of an IRSE are very low, not least owing to the already mentioned omission of wearing parts.

With an infrared spectroscopic ellipsometer, embodiments of the present invention offer all the features of an atomic force microscope: pattern or structure recognition, generation of recipes or handling instructions or execution programs, operator and engineer modes, an automatic wafer handling and an automatic real time analysis.

In combination with IRSE, one embodiment of the present invention incoporates the advantages of IRSE, which primarily reside in the long wavelength and in the size of the measurement spot. The wavelength is typically about 1.2 μm to about 16 μm and is thus greater or significantly greater than present feature sizes, in particular dimensions of shallow isolation trenches or other isolation trenches. Therefore, scattering of the light does not take place. The method according to one embodiment of the invention detects an examined layer having recesses and, if appropriate, materials arranged therein as a homogeneous thin layer made from a mixture of different materials. In the case of a measurement spot size of typically at least 300 μm×80 μm, one embodiment of the present invention provides a statistical statement about an array examined. On account of the typically large number of STI trenches within a typical measurement spot, a measurement in accordance with one embodiment of the present invention always represents an average value. Practically any quasi-random, periodic or semi-periodic STI layout can be measured.

One embodiment of the present invention enables a precise feedback or feedforward of relevant parameters without disturbing a process sequence. In particular in combination with IRSE, one embodiment of the invention may be applied to many structures, for example multilayer stacks, deep trenches, shallow trenches, two-dimensionally or three-dimensionally periodic or quasi-random structures.

One embodiment of the present invention may be applied together with or in a manner building on a physical failure analysis (PFA) to ascertain the best modeling. Furthermore, one embodiment of the present invention may be applied after a preliminary study to examine the correlation of its measurement results with those of conventional atomic force microscopy. Since process and parameter variations at deeper layers influence an IRSE spectrum in the same way as variations at upper layers or layers near the surface, variations at deeper layers may influence the statements and results with regard to an upper layer. The robustness of the modeling or the robustness of a concrete model may be examined and optimized utilizing various DOEs (DOE=Design of Experiment) and other technologies (for example, genetic algorithms).

### BRIEF DESCRIPTION OF THE DRAWINGS

Preferred exemplary embodiments of the present invention are explained in more detail below with reference to the accompanying figures, in which:

FIG. 1 shows a schematic perspective illustration elucidating a shallow trench isolation (STI);

FIG. 2 shows a perspective view of a shallow isolation trench surrounding an active region;

FIG. 3 shows schematic illustrations of vertical sections through a semiconductor structure and a model thereof;

FIG. 4 shows a schematic illustration of an infrared spectroscopic ellipsometer for use in the method according to one embodiment of the invention;

FIG. 5 shows a graph illustrating the correlation of measurement results of the method according to one embodiment of the invention and of conventional atomic force microscopy;

FIG. 6 shows a flow diagram of a method according to one embodiment of the present invention;

FIG. 7 shows a flow diagram of a method according to another embodiment of the present invention;

FIG. 8 shows a graphical illustration of a reflectivity spectrum detected according to one embodiment of the present invention; and

FIG. 9 shows a graphical illustration of reference reflectivity spectra for use with one embodiment of the present invention.

### DETAILED DESCRIPTION OF THE PREFERRED EMBODIMENT

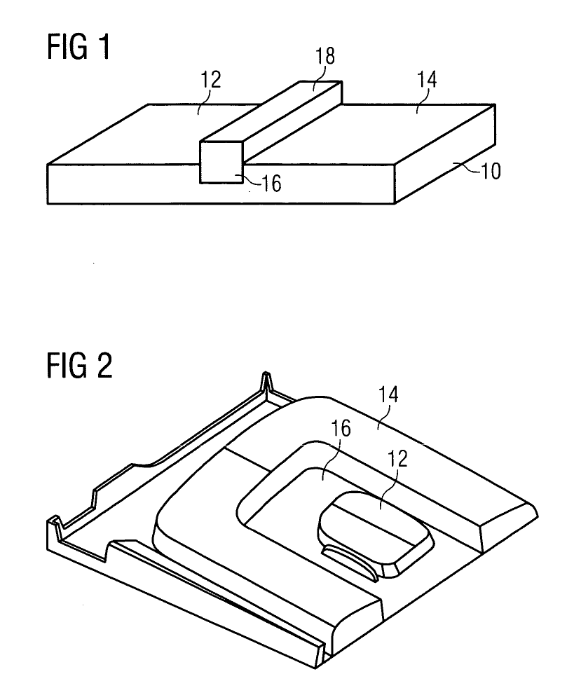

FIG. 1 is a schematic perspective illustration of a semiconductor layer 10 at a surface of a substrate (not illustrated). The semiconductor layer 10 has active regions 12, 14 in which, by way of example, individual components such as transistors, capacitors, resistors, etc., are arranged. A trench 16 is arranged between the active regions 12, 14. The trench may be filled with an insulating material 18, for example, a semiconductor oxide or a semiconductor nitride. The trench 16 may have a depth such that it completely interrupts a doped and thus electrically conductive partial layer of the semiconductor layer 10 at the surface thereof and thus electrically isolates the active regions 12, 14 from one another. The width of the trench 16 is dependent inter alia on the electrical properties, in particular, the insulation properties, of the insulating material 18.

FIG. 2 is a schematic perspective illustration of a real structure at a surface of a semiconductor layer. An illustration of this type can be produced, for example, by scanning electron microscopy or atomic force microscopy. As shown, an active region 12 is surrounded by a trench 16 which has not yet been filled with an insulating material, and is electrically isolated from an adjacent region 14 by the trench 16.

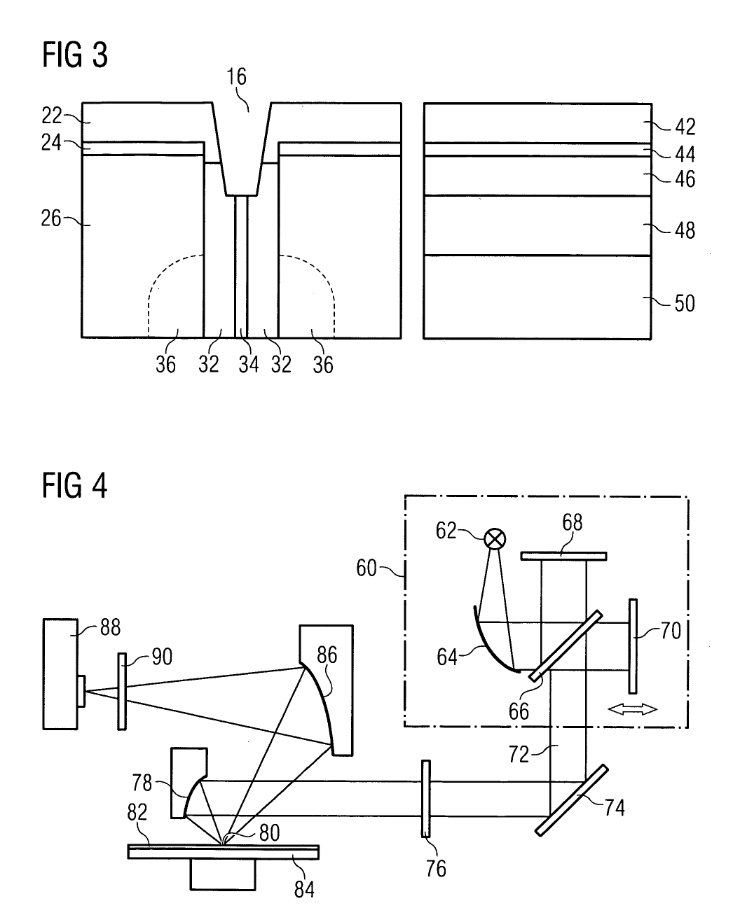

FIG. 3 is a schematic illustration of vertical sections through a real semiconductor structure (left) and a model (right) which, in contrast to the real semiconductor structure, only has laterally unpatterned or laterally homogeneous layers. The real semiconductor structure illustrated on the left in FIG. 3 may be, for example, a detail from a DRAM (dynamic random access memory) cell structure fabricated in a 0.14 μm process. The shallow trench 16 is surrounded by layers 22, 24, 26 made of different materials such as, for example, crystalline or polycrystalline silicon, silicon nitride, silicon oxide, borosilicate glass, etc. Below the trench 16, further structures 32, 34, 36 such as, for example, deep trenches filled with polysilicon, outdiffusion regions and sidewall coatings, form the actual memory cell.

On the right beside the illustration of the real structure, FIG. 3 illustrates an advantageous model of the structure which only comprises laterally unpatterned or laterally homogeneous model layers 42, 44, 46, 48, 50. The selection of the relevant layers is a key factor or an important step during modeling. The process sequence may therefore be analyzed thoroughly to ascertain, identify and/or select the relevant layers. The layer stack may be analyzed by means of PFA data that can be obtained, for example, destructively by scanning electron microscopy or secondary ion mass spectroscopy. To form an efficient model, the real structures are modeled by a stack of thin model layers. The optical indices and/or calculated dispersions (in the infrared region) of individual materials are used and “mixed” in the model layers in order to describe the real, laterally inhomogeneous structure by laterally patterned layers. This “mixing” is effected by calculations in accordance with the Bruggeman effective medium approximation (BEMA).

To put it another way, each individual model layer 42, 44, 46, 48, 50 models one of the layers 22, 24, 26 of the real component including the materials of the structures 32, 34, 36 arranged within the respective layer 22, 24, 26. Each individual model layer may have the thickness of a corresponding layer of the real structure, and the effective medium of the model layer may represent a mixture in accordance with BEMA comprising the material of the real layer and the material or materials arranged in recesses in the real layer.

This modeling is based on two assumptions. A large number of structures or recesses or trenches are measured simultaneously, i.e., are situated simultaneously within the measurement region or measurement spot that is detected. The measurement thus forms an average value over a very large number of structures. It is assumed that STI regions, in particular, represent homogeneous layers. What is observed is an effect averaged globally over the measurement region rather than an effect of individual isolation trenches or of other individual structures. The wavelength used for detecting the real structure is significantly greater than the critical dimension of an individual structure of the structures detected. This is the case for infrared light and a feature size of a few hundred nm, the wavelength being 10 to 100 times greater than the critical dimension. Scattering effects are, to a good approximation, not taken into account.

Based on these assumptions, STI regions, for example, are defined as homogeneous mixtures of materials, and the optical index of each model layer is a mixture of optical indices of the materials involved. In this case, the indices for each individual material are calculated from IRSE measurements on monitor wafers with an individual layer in each case or by means of theoretical dispersion laws (for example, the Drude law for doped silicon). The indices or the dispersion laws are then stored in a database. Based on the surface densities of the trenches, recesses and other structures and the trench dimensions which are known from a PFA analysis, the entire model is then constructed layer by layer.

Since, in accordance with one embodiment of the present invention, the respective topmost layer and the recesses arranged therein are examined and since the measurements are preferably effected after the etching of trenches or other recesses and before the filling thereof with other materials, the recesses in the topmost layer are empty. It is therefore assumed for the modeling that the filling material of the trenches or other recesses is air or vacuum. The topmost model layer 42 is thus a mixture of the material of the real layer 22 and of air or vacuum which is arranged in the trench 16. On the basis of a surface density Cx (0<Cx<1) averaged over a relatively large area for the trenches 16, the effective medium has a proportion 1−Cx of the material of the real layer 22 and a proportion Cx of vacuum or air. The effective optical index N_{eff} of the effective medium is thus N_{eff}=(1−C)·Nₘₐₜ+C·N_{void}, where N_{Void} is the optical index of air or vacuum. In accordance with this procedure, the entire real structure with the layers 22, 24, 26 and the structures 32, 34, 36 is mapped onto the laterally homogeneous model layers 42, 44, 46, 48, 50.

Instead of a BEMA calculation, for more complicated layers with more than two to three materials, alternatively and advantageously, the dispersion or the dispersion law is developed for a real layer taking account of all the different material contributions.

The application and adaptation or the fitting of the model (or its optical properties or its reflectivity spectrum) to the measured optical properties or the measured reflectivity spectrum of a real structure are effected on a production line preferably in real time. The parameters of interest are calculated and referred to the STI process properties.

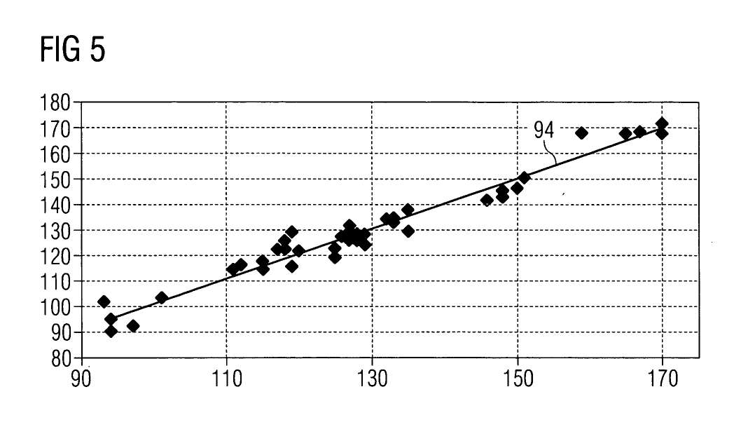

FIG. 4 is a diagram illustrating an infrared spectroscopic ellipsometer utilized to perform a method according to one embodiment of the invention. The device “IRSE 300” from the company SOPRA SA is illustrated by way of example, and this device constitutes a fully automatic system for wafer handling, for measurements and for real time data analysis. The IRSE comprises a Fourier transform spectrometer (FTS) 60. The FTS 60 comprises a broadband light source 62 that emits light in the desired spectral region, in this case in the infrared. The light source 62 is arranged at the focus of a parabolic mirror 64. By means of a semitransparent plane mirror 66, approximately half of each of the light from the light source 62 that is reflected from the parabolic mirror 64 is directed onto a rigidly mounted mirror 68 and a moveable mirror 70. The moveable mirror 70 is moved by a drive (not illustrated) periodically in oscillating fashion parallel to the normal to its surface. That proportion of the light reflected from the rigidly mounted mirror 68 which is transmitted through the semitransparent mirror 66 and that proportion of the light reflected from the moveable mirror 70 which is reflected from the semitransparent mirror 66 are superposed at the output 72 of the FTS 60. The two proportions interfere with constructive and destructive interference occurring in a manner dependent on the wavelength and the instantaneous position of the moveable mirror 70. The FTS 60 thus emits light within a broad spectral range, the wavelength-dependent intensity of which oscillates with a wavelength-dependent frequency.

The output light is deflected by a deflection mirror 74 and linearly polarized by a stationary polarizer 76. A further parabolic mirror 78 focuses the linearly polarized light onto a measurement spot or measurement region 80 at a wafer or substrate to be examined or at a layer 82 to be examined, which is held by a carrier 84. Light reflected from the layer 82 is focused onto a detector 88 such as, for example, a mercury cadmium telluride detector (MCT detector), by an ellipsoidal mirror 86. A rotatable polarizer 90 as analyzer is arranged between the ellipsoidal mirror 86 and the detector 88. Both the stationary polarizer 76 and the rotatable polarizer 90 are grating polarizers, for example. In the case of an MCT detector, the latter may be automatically cooled with liquid nitrogen every 12 hours.

The detector 88 is not wavelength-sensitive. Every wavelength that it receives has an intensity which oscillates with a frequency dependent on the wavelength, the instantaneous linear or translational velocity of the moveable mirror 70, the reflectivity of the layer 82 within the measurement spot 80 at the given wavelength, the influence of the layer 82 within the measurement spot 80 on the polarization of the reflected light, and the directions of the planes of polarization of the polarizers 76, 90. For every orientation of the rotatable polarizer 90, during one or preferably a plurality of oscillations of the moveable mirror 70, the total intensity received by the detector 88 is detected as a function of the instantaneous location of the moveable mirror 70. In the case of measuring a plurality of oscillations, the measurement results within the individual oscillations are laid over one another, added or averaged. The wavelength or frequency dependence of the reflected light is ascertained by Fourier (inverse) transformation of the dependence of the intensity signal received by the detector 88 on the location of the moveable mirror 70. From this wavelength or frequency dependence and the known frequency dependence of the light radiated in, the frequency-dependent reflectivity of the layer 82 within the measurement spot 80 may be calculated.

After carrying out these measurements for a plurality of positions of the rotatable polarizer 90, the influence of the layer 82 within the measurement spot 80 on the polarization of reflected light may be calculated as a function of the wavelength or frequency of the light. This is usually represented as a ratio ρ=Rₚ/Rₛ=tan(ψ)e^{iΔ}, where Rₚ and Rₛ are the reflectivities of the surface for a polarization parallel and perpendicular, respectively, to the plane of incidence. The so-called ellipsometric angles ψ and Δ represent the angle by which the plane of polarization is rotated during reflection and the phase difference between parallel and perpendicularly polarized partial waves. The value tan(ψ) is the amplitude ratio of the partial waves polarized parallel and perpendicularly to the plane of incidence.

The measurement described may be performed between a wave number \overline{ν}=1/λ of approximately 600 cm⁻¹ or a wavelength λ of 16.6 λm and a wave number \overline{ν} of 7 000 cm⁻¹ or a wavelength λ of approximately 1.43 λm or a wave number \overline{ν}, of approximately 8 300 cm⁻¹ or a wavelength λ of approximately 1.2 μm.

The result of the measurement is the parameter ρ(λ) or ρ(\overline{ν}) or tan (ψ(λ)) or tan (ψ(\overline{ν})) and cos (Δ(λ)) or cos (Δ(\overline{ν})) as a function of the wavelength λ or the wave number \overline{ν}. These wavelength-dependent parameters that can be represented in the form of spectra and their wavelength dependencies are in a (theoretically unambiguous) relationship with the optical properties, in particular the optical indices, of the materials and the organization of these materials within the layers (trenches, mixtures of materials, layers).

The relation between the parameter ρ(λ) and the properties of the structure examined (as a function of the wavelength λ) can be described by 2×2 Jones matrices. The properties of the structure include, in particular, dispersion laws or wavelength dependencies of optical properties of the materials that are combined to form the material structure or the material organization (stack, mixture). The thickness and the optical indices or dispersion laws are input parameters for each layer. The thickness and material of each layer of the stack are well defined by the process steps of the fabrication method.

The spectra ρ(λ) or tan (ψ(λ)) and cos (Δ(λ)) can be simulated or calculated from laterally homogeneous model layers for the model structure illustrated on the right in FIG. 3 or else from laterally patterned model layers for structures that are closer to reality. In particular, the spectra can be calculated as a function of parameters such as the lateral dimensions or volumes of the recesses in the layers and also filling factors, concentrations, material compositions and other properties of materials arranged in the recesses. By adapting or fitting a calculated to a measured spectrum over one or a plurality of the parameters mentioned, it is possible to determine values for these parameters. The smaller the number of free or unknown parameters, the more precisely all the other parameters are known and the simpler the structure examined. Thus, the more precise this fit is, the more precisely the value or values of the parameters can be determined.

The method described is furthermore more precise if radiation reflected at deep structures or at a rear side of a substrate is not concomitantly detected. In the case of the infrared spectroscopic ellipsometer illustrated in FIG. 4, this may be determined by the size of the measurement spot 80. The light reflected at the rear side of the substrate is masked out by a screen by means of the ellipsoidal mirror 86 and is thus not focused onto the detector 88. The measurement spot 80 may have a size of approximately 80 μm×300 μm.

Further parameters that influence the quality of the measurement, the meaningfulness and the accuracy of the measurement results include: the resolution of the FTS 60, the speed at which the moveable mirror 70 is moved, the inertia or temporal resolution of the detector 88, the number of oscillations or passes or scans within which measurement is effected for each position of the rotatable polarizer 90, the orientation of the stationary polarizer 76, the size of the angular steps with which the rotatable polarizer is moved in time-discrete fashion, and the speed at which the rotatable polarizer 90 is continuously moved.

FIG. 5 is a diagram illustrating the correlation between measurement results of the method according to one embodiment of the invention and a conventional measurement by atomic force microscopy. It can be discerned that the results of the conventional method and of the method according to the invention can be mapped unambiguously onto one another within a certain stochastic uncertainty. The straight line 94 illustrated represents a linear fit for which the relation y=4.6+0.96 x between the result x of the measurement by atomic force microscopy and the result y of the measurement according to the invention. Generally, however, other correlations that can be fitted by other mathematical functions are also possible.

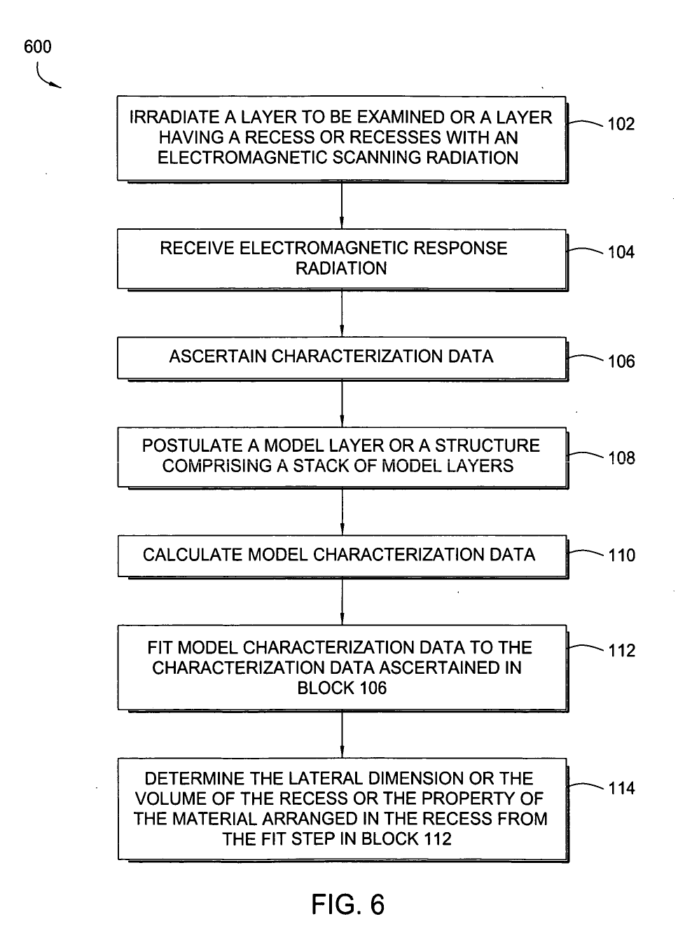

FIG. 6 is a flow diagram in which the method according to one embodiment of the invention illustrated above is represented schematically. The method 600 begins with irradiating the layer to be examined or the layer having the recess or recesses (block 102), with an electromagnetic scanning radiation that, as described above, has a wavelength greater than the feature size of the lateral structures of the layer. The wavelength of the electromagnetic scanning radiation may lie in the infrared region. This radiation may simultaneously have a plurality of wavelengths or frequencies at one and the same point in time, i.e., a discrete or continuous spectrum, such as is generated for example by the Fourier transform spectrometer 60 described above with reference to FIG. 4. As an alternative, the electromagnetic scanning radiation is monochromatic (or quasi monochromatic) or even coherent at every point in time, such as is generated for example by a grating, prism or other dispersive monochromator, or by a laser. In this case, the wavelength of the electromagnetic scanning radiation may be varied in a time-dependent manner to successively irradiate the sample with different wavelengths.

An electromagnetic response radiation emerges from the interaction between the scanning radiation and the sample, in particular the layer or layers thereof (preferably near the surface), and the response radiation generally differs from the scanning radiation in direction, intensity and polarization. This response radiation is received (block 104), and the intensity or the polarization (or both parameters) may be ascertained.

Characterization data are ascertained (block 106) from the received electromagnetic response radiation and the knowledge of the electromagnetic scanning radiation or the intensities and polarizations thereof. The characterization data characterize the interaction between the layer having the recess and the scanning radiation. In this case, the characterization data map, in a more or less transparent manner, the lateral dimension or the volume of the recess in the layer or properties of a material arranged in the recess. The characterization data comprise, by way of example, the reflectivity or transmittivity of the layer and preferably the wavelength or polarization dependence of these quantities.

In the following steps, the lateral dimension or the volume of the recess or the property of the material arranged in the recess is determined or inspected on the basis of the characterization data. For this purpose, in one embodiment, firstly a model layer or a structure comprising a stack of model layers is postulated (block 108). The model layer or the model layers may be laterally homogeneous or laterally unpatterned, as explained above with reference to FIG. 3.

Model characterization data corresponding to the abovementioned characterization data are calculated for the model layer or the structure comprising the stack of model layers (block 110). The model layer or the model structure comprising the plurality of model layers includes one or a plurality of free parameters, such that the model characterization data are dependent on the free parameter or parameters.

Afterward, the model characterization data are fitted to the characterization data ascertained in step 106 by means of the free parameter or parameters (block 112). For this purpose, the value of the free parameter (or those values of the free parameters) may be ascertained for which the model characterization data and the characterization data are identical or have a maximum similarity. In the case of the laterally homogeneous model layer, a free parameter may be, for example, the material composition or the thickness of the model layer.

In a last step, the lateral dimension or the volume of the recess or the property of the material arranged in the recess is determined (block 114) from the fit or from the value of the free parameter determined in the course of the fit step in block 112.

The method according to one embodiment of the invention illustrated with reference to FIG. 6 can be readily extended, as has already been mentioned above, to models with a plurality of model layers and/or a plurality of free parameters and the determination of a plurality of quantities from the fit step.

If the method according to one embodiment of the invention is to be used merely to monitor current production, the modeling described can be dispensed with. In this case, only the characterization data determined empirically are compared with reference characterization data. These reference characterization data are obtained by corresponding measurement at a reference layer having a known recess or more generally at a reference structure having a known layer stack and known recesses therein. If the deviations between the characterization data obtained empirically and the reference characterization data do not exceed a threshold (which is determined precisely depending on the respective application and the resulting requirements), it can be assumed that the layer examined and the reference layer do not differ or do not differ significantly. In this case, production is continued or the wafer/substrate examined is processed further.

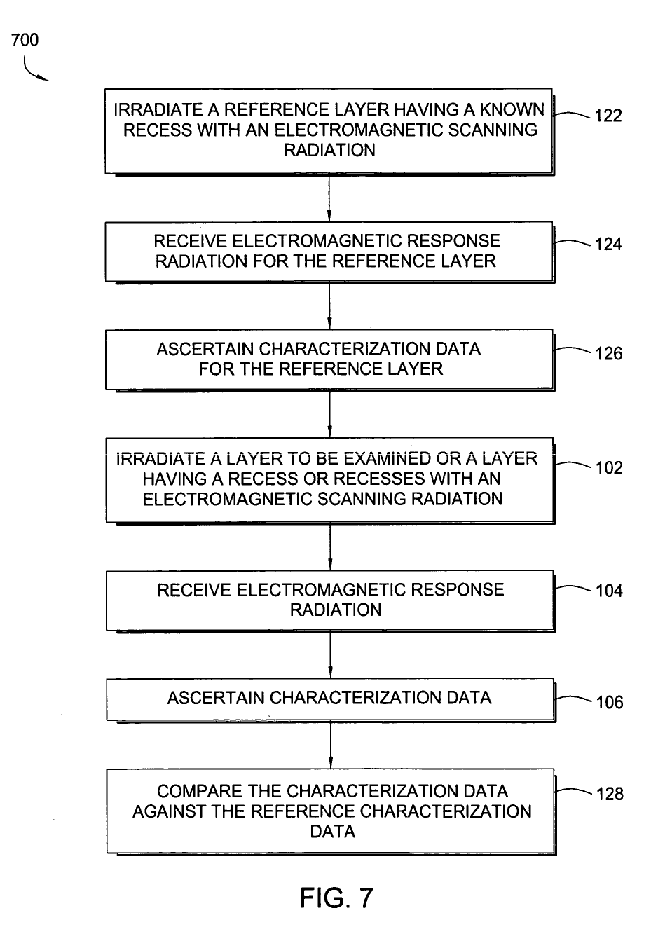

FIG. 7 is a schematic flow diagram illustrating another method 700 (a variant of the exemplary embodiment illustrated in FIG. 6) in which modeling is dispensed with, and instead, the correspondence of the layer to a reference layer is inspected merely by comparing by the characterization data obtained empirically with reference characterization data. As in the case of the exemplary embodiment illustrated in FIG. 6, the layer having the recess is irradiated with an electromagnetic scanning radiation (block 102). The electromagnetic response radiation emerging from the layer having the recess is received (block 104), and the characterization data are ascertained therefrom (block 106). Reference characterization data are ascertained by means of corresponding steps of irradiating (block 122), receiving (block 124) and ascertaining (block 126) at a reference layer having a known recess. The reference characterization data and the characterization data are compared with one another (block 128) to verify or to inspect a correspondence between the layer having the recess and the reference layer having the known recess.

In this case, it is unimportant whether the reference characterization data are obtained before or after the characterization data. In practice, however, they are generally obtained by means of steps 122, 124, 126 upon start-up of a production line or in the event of a change to relevant parameters at the latter and are subsequently used for inspecting a large number of layers by comparing the characterization data thereof with the reference characterization data.

The described method according to the invention can be carried out both with and without modeling for a single wavelength, a plurality of discrete wavelengths or a continuous spectrum of wavelengths, and for a single polarization, a plurality of discrete polarizations or a continuous spectrum of polarizations. The most extensive characterization data and therefore the most reliable and most precise statements about the layer or the layers and the recess or recesses thereof may be obtained in the course of the above-described IRSE in which measurements are performed both at a multiplicity of wavelengths and for a plurality of directions of polarization.

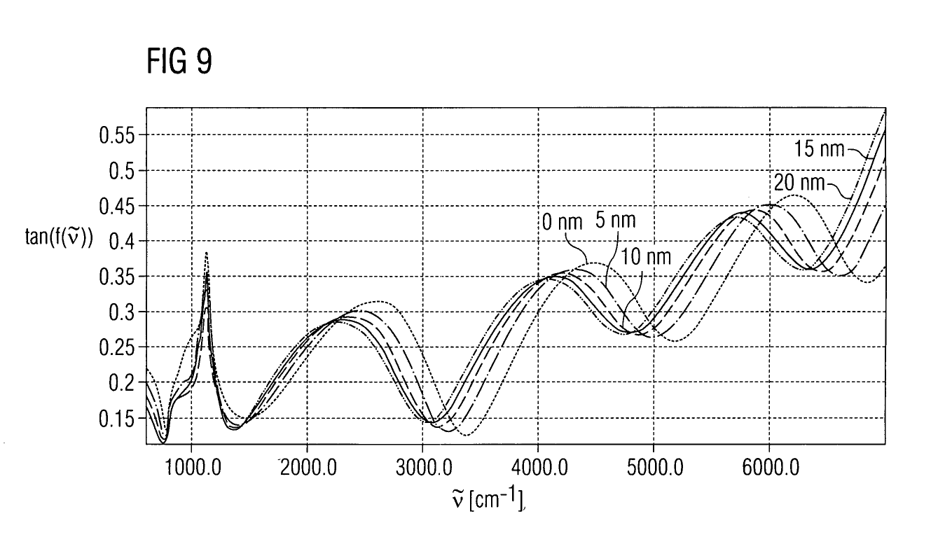

A description is given below, with reference to FIGS. 9 and 10, of a further exemplary embodiment of the present invention, in which, in contrast to the exemplary embodiment described above, on the one hand, simple infrared spectrometry also suffices instead of an infrared spectroscopic ellipsometry and, on the other hand, a sufficiently precise and reliable statement about an uncertain parameter is obtained even without modeling. The background to this exemplary embodiment involves the problem of monitoring the thickness of a sidewall coating or an edge or collar which is formed, for example, from TEOS silicon oxide (silicon oxide deposited by means of tetraethyl orthosilicate CVD) in a recess. This problem occurs in particular in the process step designated generally by R1, for example. However, the exemplary embodiment described below furthermore shows quite generally the suitability of the method according to one embodiment of the present invention for ascertaining sidewall thicknesses in two- and three-dimensional structures.

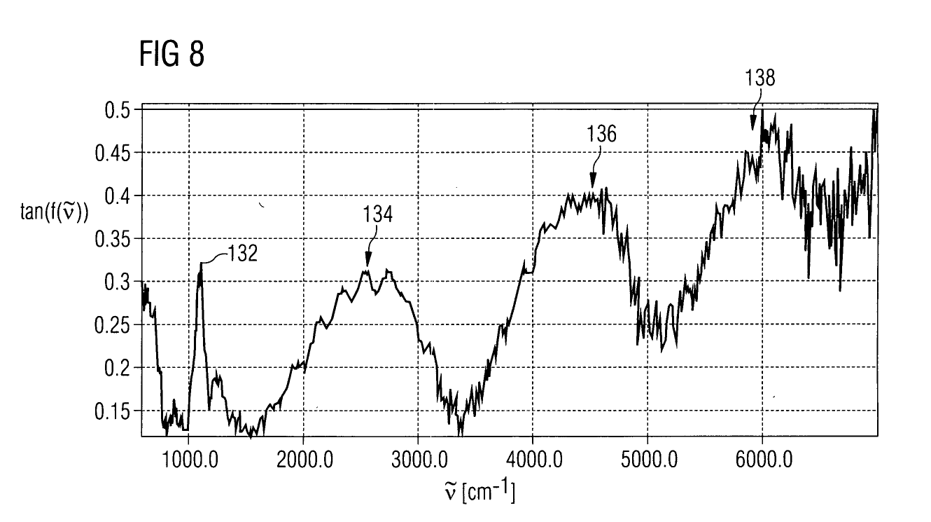

FIG. 8 is an illustration of a spectrum tan(ψ(\overline{ν})) obtained by means of IRSE. The abscissa is assigned the wave number \overline{ν}. The ordinate is assigned tan(ψ(\overline{ν})). Two types of features may be discerned in this spectrum. In the range 650 cm⁻¹≦\overline{ν}≦1500 cm⁻¹, peaks or relatively narrow spikes are visible which, in this case, can be assigned to the absorption by SiO₂ in a “collar” and an SiN layer situated at the top. While most semiconductor materials, in particular silicon, are transparent in this wavelength range, dielectric materials such as silicon oxide SiO₂ and silicon nitride SiN₂ exhibit well defined absorption peaks in this wavelength range.

A plurality of wide oscillations or maxima 134, 136, 138 can be observed in the wavelength range 1500 cm⁻¹≦\overline{ν}≦7000 cm⁻¹. The visible wide maxima 134, 136, 138 are part of a so-called fringe which lies only partly in the wavelength range illustrated and is related to the structure depth. For very shallow structures, a fringe may degenerate into a more or less shallow flank.

From the spectrum illustrated in FIG. 8, it is possible to ascertain a sidewall layer thickness by measuring the height and the form, in particular the width and the total area of the peak 132. The greater the sidewall layer thickness, the greater the height of the peak 132.

As an alternative, from the spectrum illustrated in FIG. 8, it is also possible to ascertain the sidewall layer thickness by an analysis of the fringes (in particular the position, amplitude and frequency thereof) or the degenerated fringes (in particular from the gradient thereof). Depending on the sidewall layer thickness, the position and the frequency of the fringes shift in the spectrum illustrated.

In the case of each of the two alternatives, the sidewall layer thickness is calculated by a precise analysis of the spectrum. Furthermore, both the peak 132 and the fringes or the wide maxima 134, 136, 138 thereof can be analyzed simultaneously. Three basic forms of analysis algorithms are thus available for spectral analysis. It is possible to evaluate either only the peak 132, only the fringes or the wide maxima 134, 136, 138 thereof, or the entire spectrum (peak and fringes). The last option, owing to the greater amount of processed information, may be more precise than the sole evaluation of either the peak 132 or the fringes. All three basic options may in turn be performed on a sample after the production or processing of the sidewall layer only (“post”) or both before (“pre”) and after the processing of the sidewall layer (“pre/post”). Furthermore, the algorithms can be applied to spectra which are detected either by means of infrared spectroscopy (IRS) or by means of infrared spectroscopic ellipsometry (IRSE). Consequently, twelve options result overall, although not all of them have proved to be suitable in practice hitherto. These options are compiled like a matrix in the table below (Table I). For each option, the usability of this option is indicated by a Y and the heretofore inadequate practical suitability or fundamental impossibility of the option is indicated by an N.

TABLE I

| Features used for | | | Peaks and |
|---|---|---|---|
| ascertaining characteristics | Peaks | Fringes | Fringes |
| Post IRS | Y*¹ | N*² | N |
| Post IRSE | Y | Y | Y |
| Pre/Post IRS | Y | Y | Y |
| Pre/Post IRSE | Y | Y | Y |

With regard to the exclusive evaluation of the peaks in the lower wave number range after the production of the sidewall layer, as indicated by “*1”, it should be noted that this cannot be employed if the material of the sidewall layer is also present elsewhere in the semiconductor structure. Only the detection of the peaks both before and after the processing of the sidewall layer and the comparison thereof are possible in this case.

With regard to the exclusive evaluation of the fringes after the processing of the sidewall layer by means of IRS, as indicated by “*2”, it should be noted that IRS, in contrast to IRSE, does not yield information about material compositions. However, the material composition must be known in the case of the exclusive evaluation of fringes after the processing of the sidewall layer.

FIG. 9 is a schematic illustration of a plurality of spectra tan(ψ(\overline{ν})) that were simulated for various R1 collar sidewall thicknesses of between 0 and 20 nm. It can be discerned that for a rising sidewall layer thickness, a distinct and systematic variation occurs in the spectrum tan(ψ(λ)). As a result, it is possible either to fit the calculated spectrum to a spectrum detected empirically, in order to obtain the sidewall layer thickness as a resulting fit parameter, or to compare a spectrum detected empirically with a reference spectrum, in order to inspect the sidewall layer thickness in the context of a process control. In both variants, the method according to one embodiment of the invention yields a precise, reliable and thus meaningful result.

Ascertaining a sidewall layer thickness is only one example of the applicability of the method according to one embodiment of the invention. Embodiments of the invention may furthermore be employed for a large range of structures in semiconductor materials and in particular semiconductor bulk materials, for example trenches, lines, spacings, holes of different shapes and all types of etched structures. Furthermore, the method according to one embodiment of the invention is compatible with a large range of sidewall layer materials and is not limited with regard to any basic construction rules or the structure depth.

Embodiments of the present invention may be integrated into fabrication methods. During the fabrication of a component, firstly a partly finished component is produced, which has the layer to be examined with the recess at the surface of a substrate. A lateral dimension or a volume of the recess in the layer or a property of a material arranged in the recess is ascertained or inspected according to one of the methods described above. Finally, depending on a result of the ascertaining or inspecting steps, the partly finished component is rejected or completed, and appropriate production parameters may be set or varied depending on the result. As an alternative, one or a plurality of further partly finished components are produced depending on the result (i.e., the result influencing process parameters).

While the foregoing is directed to embodiments of the present invention, other and further embodiments of the invention may be devised without departing from the basic scope thereof, and the scope thereof is determined by the claims that follow.

1. A method for inspecting a recess in a layer at a surface of a substrate, comprising:
irradiating the layer having the recess with an electromagnetic scanning radiation having a wavelength greater than a lateral dimension of the recess;
receiving an electromagnetic response radiation resulting from an interaction between the scanning radiation and the layer having the recess;
ascertaining characterization data, from the received electromagnetic response radiation, wherein the characterization data characterize the interaction between the layer having the recess and the scanning radiation and maps at least one of a lateral dimension of the recess, a volume of the recess and a property of a material disposed in the recess; and
determining at least one of the lateral dimension of the recess, the volume of the recess and the property of the material disposed in the recess based on the characterization data.

2. The method of claim 1, wherein the determining step comprises:
postulating a model structure comprising one or more model layers with one or more free parameters;
calculating model characterization data that characterize an interaction of the model structure with the scanning radiation, the model characterization data being dependent on the free parameter;
ascertaining one or more values of the one or more free parameters for which the model characterization data and the characterization data are substantially similar; and
determining at least one of the lateral dimension of the recess, the volume of the recess and the property of the material disposed in the recess based on the ascertained one or more values of the one or more free parameters.

3. The method of claim 2, wherein at least one model layer is laterally homogeneous, wherein a respective free parameter describes at least one of a material composition and a thickness of the at least one model layer.

4. The method of claim 1, further comprising:
irradiating a reference layer having a known recess with the electromagnetic scanning radiation having a wavelength greater than a lateral dimension of the known recess;
receiving a reference electromagnetic response radiation resulting from an interaction of the scanning radiation with the reference layer having the known recess;
ascertaining reference characterization data from the received reference electromagnetic response radiation, wherein the reference characterization data characterize the interaction of the reference layer having the known recess with the scanning radiation; and
comparing the characterization data with the reference characterization data to determine at least one of whether the recess and the known recess have a same lateral dimension, whether the recess and the known recess have a same volume and whether the recess and the known recess have a same property of the material disposed therein.

5. The method of claim 1, wherein the characterization data is represented by at least one of a height, a width and an area of an absorption line in a spectrum.

6. The method of claim 1, wherein the layer is irradiated with electromagnetic scanning radiation having a plurality of wavelengths and wherein the characterization data comprise a reflectivity spectrum.

7. The method of claim 1, wherein the scanning radiation is linearly polarized and the step of receiving the electromagnetic response radiation comprises ascertaining the polarization of the response radiation.

8. The method of claim 1, wherein a thickness of the layer having the recess is less than the wavelength of the electromagnetic scanning radiation.

9. The method of claim 1, wherein the recess is an isolation trench.

10. The method of claim 1, wherein the property of the material disposed in the recess is one of a material composition, a material concentration and a filling factor of the material.

11. The method of claim 1, wherein the property of the material arranged in the recess is a thickness of a sidewall layer made from the material.

12. The method of claim 1, wherein the layer is a semiconductor layer or the substrate is a semiconductor substrate.

13. The method of claim 1, wherein a region of the layer having a plurality of recesses is irradiated.

14. The method of claim 1, wherein the wavelength is between about 1.2 μm and about 16.6 μm.

15. A method for fabricating a component, comprising:
producing a partly finished component on a substrate with a layer having a recess disposed at a surface of the substrate;
determining at least one of a lateral dimension of the recess, a volume of the recess and a property of a material arranged in the recess; and
continuing processing the partly finished component based on a result of the determining step.

16. The method of claim 15, wherein the determining step comprises:
irradiating the layer having the recess with an electromagnetic scanning radiation having a wavelength greater than a lateral dimension of the recess;
receiving an electromagnetic response radiation resulting from an interaction between the scanning radiation and the layer having the recess;
ascertaining characterization data, from the received electromagnetic response radiation, wherein the characterization data characterize the interaction between the layer having the recess and the scanning radiation and maps at least one of the lateral dimension of the recess, the volume of the recess and the property of the material disposed in the recess; and
determining at least one of the lateral dimension of the recess, the volume of the recess and the property of the material disposed in the recess based on the characterization data.

17. The method of claim 16, wherein the determining step further comprises:
postulating a model structure comprising one or more model layers with one or more free parameters;
calculating model characterization data that characterize an interaction of the model structure with the scanning radiation, the model characterization data being dependent on the free parameter;
ascertaining one or more values of the one or more free parameters for which the model characterization data and the characterization data are substantially similar; and
determining at least one of the lateral dimension of the recess, the volume of the recess and the property of the material disposed in the recess based on the ascertained one or more values of the one or more free parameters.

18. The method of claim 16, wherein the determining step further comprises:
comparing the characterization data with a reference characterization data to determine at least one of whether the recess and the known recess have a same lateral dimension, whether the recess and the known recess have a same volume and whether the recess and the known recess have a same property of the material disposed therein.

19. The method of claim 15, further comprising:
identifying a defectively processed component based on the result of the determining step; and
removing the defectively processed component from further processing.

20. The method of claim 15, further comprising:
changing subsequent processing parameters based on the result of the determining step.
